(19) United States
(12) Patent Application Publication
(10) Pub. No.: US 2026/0194592 A1
(43) Pub. Date: Jul. 9, 2026

(54) IMPEDANCE MEASURING DEVICE

(71) Applicant: DENSO CORPORATION, Kariya-city (JP)

(72) Inventors: Masaaki KITAGAWA, Kariya-city (JP); Hajime KOSUGI, Kariya-city (JP)

(73) Assignee: DENSO CORPORATION, Kariya-city (JP)

(21) Appl. No.: 19/554,065

(22) Filed: Mar. 2, 2026

Related U.S. Application Data
(63) Continuation of application No. PCT/JP2024/027886, filed on Aug. 5, 2024.

(30) Foreign Application Priority Data
Aug. 29, 2023 (JP) 2023-139238

(51) Int. Cl. G01R 31/389; B60L 50/60; G01R 31/3842; G01R 31/392; G01R 31/396

(52) U.S. Cl. CPC G01R 31/389; B60L 50/60; G01R 31/3842; G01R 31/392; G01R 31/396

(57) ABSTRACT

An impedance measuring device includes a plurality of electrical paths connected to both ends of each battery cells connected in series, an AC current generating unit that allows an AC current to flow through the battery cells, a voltage fluctuation measuring unit that measures voltage fluctuations in response to the AC current, a connection operation unit that, when measuring the impedance of a cell to be measured, causes the AC current of the AC current generating unit to flow through a pair of electrical paths that are on the positive and negative sides of the cell to be measured, and connects the voltage fluctuation measuring unit to a pair of electrical paths that are also on the positive and negative sides of the cell to be measured, but that are a different combination from the pair of electrical paths through which the AC current of the AC current generating unit flows, and a calculation unit that calculates the impedance value of the cell to be measured based on an amplitude and a voltage fluctuation of the AC current.

### CROSS-REFERENCE TO RELATED APPLICATION

The present application is based on and claims the benefit of priority from earlier Japanese Patent Application No. 2023-139238 filed on Aug. 29, 2023, the descriptions of which are incorporated herein by reference.

### TECHNICAL FIELD

The present disclosure relates to an impedance measuring device.

### BACKGROUND

Conventionally, in order to monitor the state of a storage battery, an impedance of the storage battery is measured (for example, see JP 2021-12065 A). Specifically, a battery monitoring device passes an AC current through the storage battery, acquires the voltage fluctuations that occur as a response signal, and calculates the impedance value of the storage battery based on the amplitude of the AC current and the voltage fluctuations.

### SUMMARY

In order to solve the above problems, the present disclosure provides:
an impedance measuring device for a battery module having a plurality of battery cells connected in series and measures an impedance of the battery cells, the impedance measuring device comprising:
a plurality of electrical paths respectively connected to both ends of respective battery cells,
an AC current generating unit connected to the electrical paths and supplying an AC current to the battery cells,
a voltage fluctuation measuring unit connected to the electrical paths and configured to measure voltage fluctuations responsive to the AC current of the AC current generating unit,
a connection operation unit that, when measuring impedance of one of the plurality of battery cells as a cell to be measured, causes the AC current of the AC current generating unit to flow through a pair of electrical paths that are on positive and negative sides of the cell to be measured in a series connection path of the plurality of battery cells, and connects the voltage fluctuation measuring unit to the pair of electrical paths that are on the positive and negative sides of the cell to be measured, and that are a different combination from the pair of electrical paths through which the AC current of the AC current generating unit flows, and
a calculation unit that calculates an impedance value of the cell to be measured based on an amplitude of the AC current flowing from the AC current generating unit and a voltage fluctuation measured by the voltage fluctuation measuring unit in a connected state produced by the connection operation unit, wherein
when measuring the impedance of the cell to be measured, the connection operation unit causes the AC current from the AC current generating unit to flow through the electrical paths at both ends of the cell to be measured, and connects the voltage fluctuation measuring unit to the electrical paths at both ends of a battery cell group including at least the cell to be measured and the battery cells on both sides of the cell to be measured, and
the calculation unit causes the AC current from the AC current generating unit to flow through the electrical paths between both ends of the cell to be measured, and the voltage fluctuation measuring unit is connected to the electrical paths between both ends of the battery cell group, and calculates the impedance value of the cell to be measured based on the amplitude of the AC current flowing from the AC current generating unit and the voltage fluctuation measured by the voltage fluctuation measuring unit.

### BRIEF DESCRIPTION OF THE DRAWINGS

The above features of the present disclosure will be made clearer by the following detailed description, given referring to the appended drawings. In the accompanying drawings:

FIG. 1 shows an electrical circuit diagram of a power supply system;

FIG. 2 shows a block diagram of a battery monitoring unit;

FIG. 3 is a circuit diagram showing a specific circuit configuration of the battery monitoring unit;

FIG. 4 shows a diagram for explaining a specific method for measuring impedance;

FIG. 5 shows a flowchart illustrating a battery monitoring process;

FIG. 6 shows a diagram for explaining a specific method for measuring impedance;

FIG. 7 shows a diagram for explaining a specific method for measuring impedance of a highest potential cell;

FIG. 8 shows a diagram for explaining a specific method for measuring impedance of a lowest potential cell;

FIG. 9 is a diagram for explaining a specific method for measuring impedance in a second embodiment;

FIG. 10 shows a flowchart illustrating a battery monitoring process in the second embodiment;

FIG. 11 shows a diagram for explaining a specific method for measuring impedance of a highest potential cell;

FIG. 12 shows a diagram for explaining a specific method for measuring impedance of a lowest potential cell;

FIG. 13 is a plan view showing a stacked state of cells in a battery module according to a third embodiment;

FIG. 14 shows a diagram for explaining a specific method for measuring impedance;

FIG. 15 shows a schematic diagram illustrating a closed-circuit region during impedance measurement of a battery cell;

FIG. 16 shows a diagram for explaining a specific method for measuring impedance;

FIG. 17 shows a schematic diagram illustrating a closed-circuit region during impedance measurement of a battery cell;

FIG. 18 shows a perspective view illustrating another configuration of a battery module; and

FIGS. 19A and 19B show time charts showing on/off operation of each switch.

### DETAILED DESCRIPTION OF THE PREFERRED EMBODIMENTS

When measuring impedance, it is conceivable to pass an AC current through an electrical path connected to both ends of the storage battery, and measure the voltage fluctuations in the electrical path through which the AC current flows using a voltage measuring unit. In this case, there is a concern that an error in measuring the voltage fluctuations may occur due to the common path for applying AC current and for measuring the voltage, resulting in a decrease in the accuracy of impedance measurement. That is, a voltage drop occurs in the electrical path through which the AC current flows due to wiring resistance and the AC current itself, and if the voltage drop reduces the accuracy of voltage measurement, the accuracy of impedance measurement also reduces.

The present disclosure has been made in view of the above-mentioned problems, and has an object to provide an impedance measuring device that can improve the accuracy of impedance measurement.

In order to solve the above problems, the present disclosure provides:
an impedance measuring device for a battery module having a plurality of battery cells connected in series and measures an impedance of the battery cells, the impedance measuring device comprising:
a plurality of electrical paths respectively connected to both ends of respective battery cells,
an AC current generating unit connected to the electrical paths and supplying an AC current to the battery cells,
a voltage fluctuation measuring unit connected to the electrical paths and configured to measure voltage fluctuations responsive to the AC current of the AC current generating unit,
a connection operation unit that, when measuring impedance of one of the plurality of battery cells as a cell to be measured, causes the AC current of the AC current generating unit to flow through a pair of electrical paths that are on positive and negative sides of the cell to be measured in a series connection path of the plurality of battery cells, and connects the voltage fluctuation measuring unit to the pair of electrical paths that are on the positive and negative sides of the cell to be measured, and that are a different combination from the pair of electrical paths through which the AC current of the AC current generating unit flows, and
a calculation unit that calculates an impedance value of the cell to be measured based on an amplitude of the AC current flowing from the AC current generating unit and a voltage fluctuation measured by the voltage fluctuation measuring unit in a connected state produced by the connection operation unit, wherein
when measuring the impedance of the cell to be measured, the connection operation unit causes the AC current from the AC current generating unit to flow through the electrical paths at both ends of the cell to be measured, and connects the voltage fluctuation measuring unit to the electrical paths at both ends of a battery cell group including at least the cell to be measured and the battery cells on both sides of the cell to be measured, and
the calculation unit causes the AC current from the AC current generating unit to flow through the electrical paths between both ends of the cell to be measured, and the voltage fluctuation measuring unit is connected to the electrical paths between both ends of the battery cell group, and calculates the impedance value of the cell to be measured based on the amplitude of the AC current flowing from the AC current generating unit and the voltage fluctuation measured by the voltage fluctuation measuring unit.

In the above configuration, when measuring the impedance of the cell to be measured, the AC current from the AC current generating unit is caused to flow through the pair of electrical paths that are on the positive and negative sides of the cell to be measured in the series connection path of the plurality of battery cells, and the voltage fluctuation measuring unit is connected to the pair of electrical paths that are on the positive and negative sides of the cell to be measured and that are a different combination from the pair of the electrical paths through which the AC current from the AC current generating unit flows. In this case, the electrical path through which the AC current flows and the electrical path through which the voltage fluctuation is measured are different. Then, in this path connection state, the impedance value of the cell to be measured is calculated based on the amplitude of the AC current flowing from the AC current generating unit and the voltage fluctuation measured by the voltage fluctuation measuring unit. This makes it possible to suppress the inconvenience of a voltage drop from occurring due to the wiring resistance and the AC current when the AC current flows, such as a decrease in the accuracy of measuring the voltage fluctuations due to the voltage drop. As a result, the accuracy of measuring the impedance can be improved.

A power supply system according to the present embodiment will be described below. In the present embodiment, a power supply system mounted on an electrically powered vehicle such as a hybrid vehicle or an electric vehicle will be described with reference to the drawings.

### First Embodiment

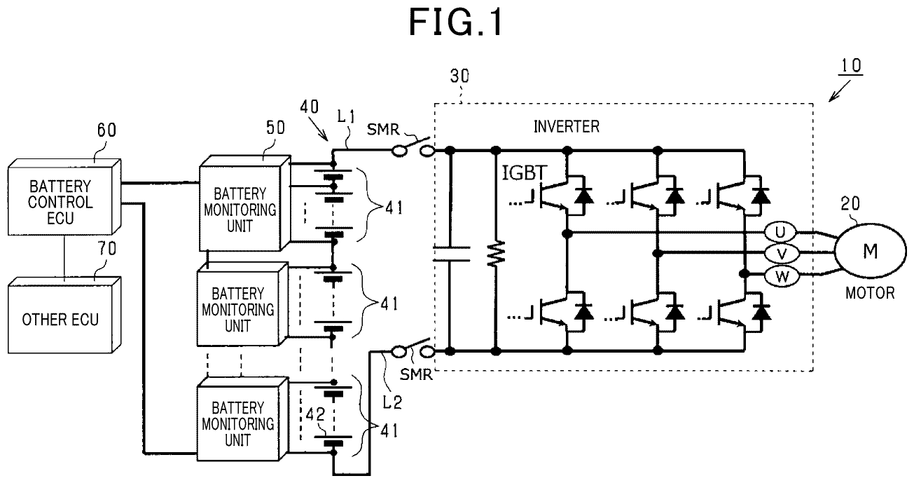

As shown in FIG. 1, a power supply system 10 includes a motor 20 as a rotating electric machine, an inverter 30 as a power converter that supplies three-phase current to the motor 20, a chargeable and dischargeable battery pack 40 (secondary battery), a battery monitoring unit 50 that monitors a state of the battery pack 40, a battery control ECU 60 that controls the battery pack 40, and other ECUs 70 such as a motor ECU that controls the motor 20. The battery monitoring unit 50 is, for example, a CSC (Cell Supervision Circuit). The battery control ECU 60 may be, for example, a BMU (Battery Management Unit).

The motor 20 (a motor generator) is an in-vehicle main engine, and is capable of transmitting power to drive wheels (not shown). In the present embodiment, the motor 20 is a three-phase permanent magnet synchronous motor. The inverter 30 is configured with a full-bridge circuit having the same number of upper and lower arms as the number of phases of the phase windings, and the current flowing in each phase winding is adjusted by turning on and off a switch (semiconductor switching element) provided in each arm. An IGBT (Insulated Gate Bipolar Transistor) may be used as the switch, for example.

The inverter 30 is provided with an inverter control device (not shown), which controls the flow of current by turning on and off each switch in the inverter 30 based on various detection information from the motor 20 and requirements for power driving and power generation. As a result, the inverter control device supplies power from the battery pack 40 to the motor 20 via the inverter 30, and drives the motor 20 in power running mode. In addition, when the motor 20 generates power using power from the drive wheels, the inverter control device converts the generated power via the inverter 30 and supplies it to the battery pack 40 to charge the battery pack 40.

The battery pack 40 is electrically connected to the motor 20 via the inverter 30. The battery pack 40 has an inter-terminal voltage of, for example, 100 V or more, and is configured by connecting a plurality of battery modules 41 in series. The battery module 41 is configured by connecting a plurality of battery cells 42 in series. A lithium iron phosphate battery (LFP battery), a lithium-ion battery, or a nickel-metal hydride battery can be used as the battery cell 42, for example. Each battery cell 42 is a storage battery having an electrolyte (a solution consisting of an electrolyte and a solvent) and a plurality of electrodes.

Although not shown as this is well known, each battery cell 42 has a positive terminal and a negative terminal, and the battery module 41 is configured such that the positive terminals and negative terminals of different battery cells 42 in the series connection order are electrically connected by conductive members such as bus bars. Note that in each battery cell 42, the positive terminal and the negative terminal may be arranged side by side on the same side of the battery cell 42, or may be arranged on two different sides of the battery cell 42 (for example, on the side at one end and the side at the other end in the longitudinal direction of the cell).

As shown in FIG. 1, a positive terminal of an electrical load such as an inverter 30 is connected to a positive electrode side power supply path L1 connected to a positive electrode side power supply terminal of the battery pack 40. Similarly, a negative terminal of an electrical load such as the inverter 30 is connected to a negative electrode side power supply path L2 connected to a negative electrode side power supply terminal of the battery pack 40. Note that the positive electrode side power supply path L1 and the negative electrode side power supply path L2 are each provided with a relay switch SMR (system main relay switch), which is configured to be able to switch between energizing and de-energizing.

The battery monitoring unit 50 is provided for each battery module 41. The battery monitoring unit 50 is a device that monitors the state of charge (SOC) and the state of health (SOH) of each battery cell 42. The battery monitoring unit 50 is capable of communicating with the battery control ECU 60, and measures and outputs a complex impedance (impedance), etc. of each battery cell 42.

The other ECU 70 requests the inverter control device to perform power running and generate electricity based on various types of information. The various types of information include, for example, accelerator and brake operation information, vehicle speed, and the state of the battery pack 40. In addition, the other ECU 70 also receives input of the results of measuring the state of each battery cell 42 from the battery control ECU 60.

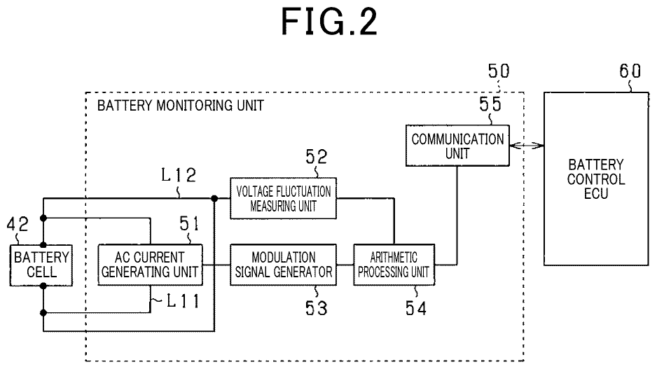

Next, the battery monitoring unit 50 will be described in detail. As shown in FIG. 2, the battery monitoring unit 50 is disposed so as to be able to measure the battery state of each battery cell 42. The battery monitoring unit 50 includes an AC current generating unit 51 connected to the battery cell 42 via an electrical path L11, and a voltage fluctuation measuring unit 52 connected to the battery cell 42 via an electrical path L12. In addition, the battery monitoring unit 50 also includes a modulation signal generator 53 connected to the AC current generating unit 51, an arithmetic processing unit 54 connected to the voltage fluctuation measuring unit 52 and the modulation signal generator 53, and a communication unit 55 connected to the arithmetic processing unit 54.

The AC current generating unit 51 outputs an AC current using the battery cell 42, which is the measurement target, as a power source. More specifically, the AC current generating unit 51 causes the battery cell 42 to output the AC current based on an instruction signal input from the modulation signal generator 53. When the AC current flows from the battery cell 42, a response signal (voltage fluctuation) that reflects information about the complex impedance occurs in the inter-terminal voltage of the battery cell 42. The voltage fluctuation measuring unit 52 measures the response signal (voltage fluctuation) that reflects information on the complex impedance of the battery cell 42 between the terminals of the battery cell 42.

It should be noted that the voltage fluctuation can be calculated, for example, by subtracting the inter-terminal voltage of the battery cell 42 under measurement measured during the input of the AC current from the inter-terminal voltage of the battery cell 42 under measurement measured before the input of the AC current.

The modulation signal generator 53 includes an oscillator that generates an AC signal of an arbitrary waveform. Then, the modulation signal generator 53 causes the oscillator to generate the AC signal in accordance with an instruction from the arithmetic processing unit 54.

Although the AC signal in the present embodiment is a sine wave signal, it may be changed arbitrarily as long as it is an AC signal, and may be a square wave, a triangular wave, or the like. In addition, a DC bias is applied to the AC signal so that the AC current flowing from the battery cell 42 does not become a negative current (a reverse current to the battery cell 42).

The modulation signal generator 53 then converts the AC signal into a digital signal to generate an instruction signal, and instructs (outputs) the AC current generating unit 51 to generate an AC current based on the instruction signal.

The arithmetic processing unit 54 includes a microcomputer including a CPU (arithmetic unit) and a storage device (various memories), and realizes various functions by executing programs stored in the storage device. The various functions may be realized by electronic circuits, which are hardware, or may be realized by both hardware and software.

The arithmetic processing unit 54 has a function of calculating the complex impedance of the battery cell 42, and corresponds to a calculation unit. Here, an outline of a method for calculating the complex impedance will be described. The arithmetic processing unit 54 instructs the modulation signal generator 53 to set a measurement frequency for the complex impedance. The modulation signal generator 53 generates an AC current from the battery cell 42 via the AC current generating unit 51 based on instructions from the arithmetic processing unit 54. The voltage fluctuation measuring unit 52 measures the inter-terminal voltage of the battery cell 42, measures a response signal (voltage fluctuation) that responds to the AC current, and outputs the measured response signal to the arithmetic processing unit 54.

The arithmetic processing unit 54 calculates information about the complex impedance of the battery cell 42 based on the response signal. The arithmetic processing unit 54 repeats this series of processes until the complex impedances for a plurality of predetermined measurement frequencies within a measurement range are calculated. In addition, the arithmetic processing unit 54 also notifies the battery control ECU 60 of the calculation result. The battery control ECU 60 creates, for example, a complex impedance plane plot (Cole-Cole plot) based on the calculation results, and understands the characteristics of electrodes, electrolyte, etc. In addition, it also understands the state of charge (SOC) and the state of health (SOH).

Note that it is not necessary to create the entire Cole-Cole plot, but rather it is possible to focus on a part of it. For example, the complex impedance of a specific frequency may be measured at regular time intervals while the vehicle is running, and changes in the SOC, the SOH, the battery temperature, etc. while the vehicle is running may be determined based on the time variation in the complex impedance of the specific frequency. Alternatively, the complex impedance at a specific frequency may be measured at time intervals such as once a day, once a week, or once a year, and changes in the SOH, etc. may be determined based on the time variation in the complex impedance of the specific frequency. In addition, the complex impedance plane plot is not limited to the Cole-Cole plot, but a Bode plot or the like may also be used.

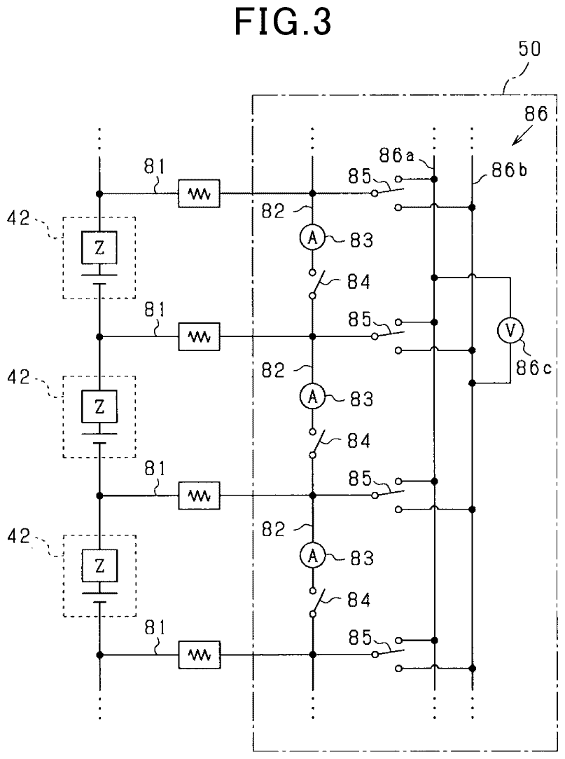

FIG. 3 is a circuit diagram showing a specific circuit configuration of the battery monitoring unit 50. FIG. 3 shows three battery cells 42 connected in series, with electrical paths 81 connected to both ends of each battery cell 42. The electrical path 81 is made of electrical wiring. Each battery cell 42 has an impedance component Z, and each electrical path 81 has a wiring resistance component.

The battery monitoring unit 50 includes connection paths 82 that connect the electrical paths 81 extending from both ends of each battery cell 42 to each battery cell 42. A current sensor 83 and a switch 84 are disposed for each battery cell 42 in the connection path 82. The switch 84 is a semiconductor switching element such as a MOSFET. The switch 84 constitutes an equalization circuit that equalizes the charge amount of each battery cell 42, and by turning on the switch 84, each battery cell 42 is discharged, thereby eliminating variations in the charge amount of each battery cell 42. Note that it is preferable that at least one of the electrical paths 81 and 82 is provided with a resistor. This resistor serves to adjust the current during impedance measurement or during equalization.

The current sensor 83 may be disposed in the electrical path 81. In short, the current sensor 83 may be disposed anywhere on a closed circuit formed by the battery cell 42, electrical paths 81 and 82, and switch 84, as long as it is disposed outside the path near the battery through which inverter current, etc., flows. The current sensor 83 may be configured, for example, by a resistor (for example, a shunt resistor) and a voltmeter. Although not shown, a shunt resistor may be disposed outside the battery monitoring unit 50, for example, in the electrical path 81, and the voltage across the shunt resistor may be measured by the battery monitoring unit 50. The resistor that adjusts the current during impedance measurement and equalization may also function as a shunt resistor for the current sensor 83.

The switch 84 constitutes the AC current generating unit 51 shown in FIG. 2, and by turning the switch 84 on and off at a predetermined cycle, a predetermined AC signal (AC current) is output using the battery cell 42 as a power source.

In addition, a voltage measurement circuit 86 is connected to each electrical path 81 via a switch 85. The voltage measurement circuit 86 includes a positive electrode side path 86a, a negative electrode side path 86b, and a voltage sensor 86c connected to each of the paths 86a and 86b. Each electrical path 81 can be selectively connected to the positive electrode side path 86a and the negative electrode side path 86b of the voltage measurement circuit 86 by each switch 85. In other words, each switch 85 can be switched between a state in which the electrical path 81 and the voltage measurement circuit 86 are disconnected (the state shown in the drawing), a state in which the electrical path 81 is connected to the positive electrode side path 86a of the voltage measurement circuit 86, and a state in which the electrical path 81 is connected to the negative electrode side path 86b of the voltage measurement circuit 86. By operating each switch 85, the battery cell 42 that is a target of voltage measurement in the voltage measurement circuit 86 is switched. The voltage measurement circuit 86 measures the inter-terminal voltage of each battery cell 42.

The voltage measurement circuit 86 constitutes the voltage fluctuation measuring unit 52 shown in FIG. 2, and the voltage fluctuation measuring unit 52 calculates the voltage fluctuation responsive to the AC current of the AC current generating unit 51 from the inter-terminal voltage of the battery cell 42 measured by the voltage measurement circuit 86.

When measuring the impedance of the battery cells 42, one of the pluralities of battery cells 42 is selected as a cell to be measured, and the impedance of that cell to be measured is measured. In this case, the switch 84 on the path connecting both ends of the cell to be measured is turned on and off, causing an AC current to flow through the cell to be measured. Then, in this state, the voltage fluctuations in response to the AC current are measured by the voltage measurement circuit 86. In addition, in the voltage fluctuation measuring unit 52 shown in FIG. 2, the voltage fluctuation is calculated from the measured voltage of the voltage measurement circuit 86, and in the arithmetic processing unit 54, the impedance value of the cell being measured is calculated based on the amplitude of the AC current and the amount of voltage fluctuation.

Incidentally, when measuring impedance, an AC current is passed through the electrical path 81 connected to both ends of the cell to be measured, and voltage fluctuations are measured via the electrical path 81 also connected to both ends of the cell to be measured. In this case, there is a concern that an error in measuring voltage fluctuations may occur due to a common path for flowing AC current and for measuring voltage, resulting in a decrease in the accuracy of impedance measurement. That is, a voltage drop occurs in the electrical path 81 through which the AC current flows due to the wiring resistance and the AC current itself, and if the voltage drop reduces the accuracy of voltage measurement, the accuracy of impedance measurement also reduces.

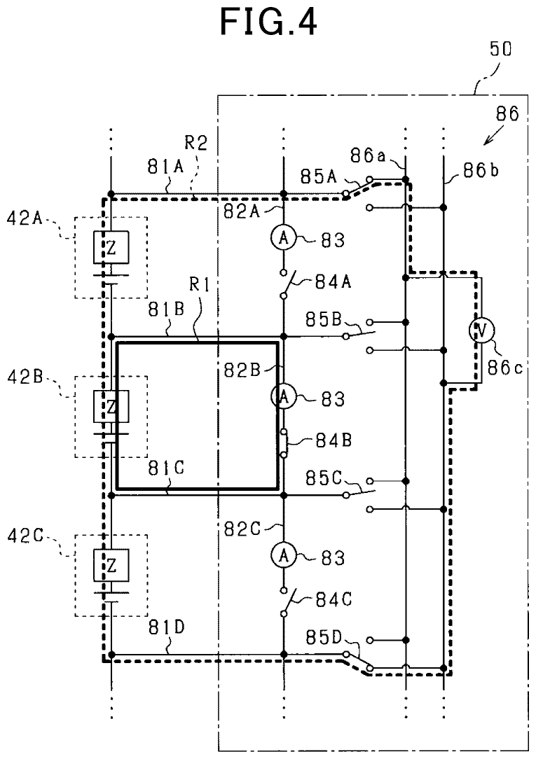

Therefore, when measuring impedance, the electrical path 81 through which the AC current is passed by the AC current generating unit 51 is different from the electrical path 81 through which the voltage fluctuation is measured by the voltage fluctuation measuring unit 52 (voltage measurement circuit 86), thereby suppressing a decrease in the accuracy of impedance measurement. That is, in the present embodiment, the AC current from the AC current generating unit 51 is caused to flow through a pair of electrical paths 81 that are on the positive and negative sides of the cell to be measured in the series connection path of the plurality of battery cells 42, and the voltage fluctuation measuring unit 52 is connected to a pair of electrical paths 81 that are on the positive and negative sides of the cell to be measured, but that are a different combination from the pair of electrical paths 81 through which the AC current from the AC current generating unit 51 flows. A specific method for measuring impedance will be described below with reference to FIG. 4.

FIG. 4 shows a state in which impedance measurement is carried out on three battery cells 42 connected in series as battery cells 42A to 42C, with the battery cell 42B being the cell to be measured. In FIG. 4, the connection paths 82 and the switches 84 provided for the battery cells 42A to 42C are respectively referred to as the connection paths 82A to 82C and the switches 84A to 84C. In addition, the electrical paths 81 are referred to as the electrical paths 81A to 81D, and the switches 85 connected to the electrical paths 81A to 81D are referred to as the switches 85A to 85D. Note that the wiring resistances of the electrical paths 81 are not shown. In FIG. 4, a path R1 through which an AC current flows is indicated by a thick solid line, and a path R2 through which a voltage is measured is indicated by a thick dashed line.

When the battery cell 42B is the cell to be measured, among the switches 84A to 84Cthe switch 84B on the path connecting both ends of the battery cell 42B is turned on and off at a predetermined cycle, causing an AC current to flow through the battery cell 42B. At this time, the AC current flows through a path R1 including the battery cell 42B, the electrical paths 81B and 81C at both ends of the battery cell 42B, and the connection path 82B.

In addition, the voltage measurement circuit 86 measures the inter-terminal voltage of a battery cell group including the battery cell 42B and the battery cells 42A and 42C adjacent to the battery cell 42B. Specifically, by switching the switch 85A, the positive electrode side electrical path 81A of the battery cell 42A is connected to the positive electrode side path 86a of the voltage measurement circuit 86, and by switching the switch 85D, the negative electrode side electrical path 81D of the battery cell 42C is connected to the negative electrode side path 86b of the voltage measurement circuit 86. As a result, voltage fluctuations are measured on a path R2 that includes the battery cell group of the battery cells 42A to 42C, the electrical paths 81A and 81D at both ends of the battery cell group, and the voltage measurement circuit 86. Then, the impedance value of the battery cell 42B is calculated based on the voltage fluctuation measured by the voltage measurement circuit 86 and the amplitude of the AC current measured by the current sensor 83.

As described above, the AC current path and the voltage measurement path are appropriately switched by controlling the on/off of the switches 84 and 85. The on/off control of each switch 84, 85 may be performed by the arithmetic processing unit 54, which corresponds to a connection operation unit.

Note that in the voltage measurement circuit 86, three battery cells 42 including the cell to be measured (battery cell 42B) and the battery cells 42A and 42C adjacent to it are configured to measure the inter-terminal voltage, however, this configuration may be any as long as the inter-terminal voltage is measured for a group of battery cells including at least the cell to be measured and the battery cells 42 adjacent to it. That is, the battery cell group that is the subject of voltage fluctuation measurement may include one or more battery cells 42 on both the positive and negative sides of the cell that is the subject of measurement.

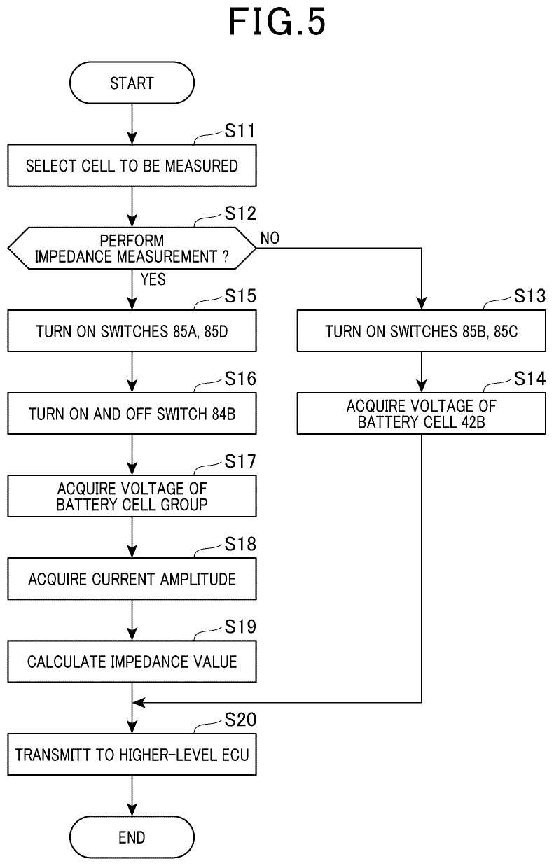

FIG. 5 is a flowchart showing a battery monitoring process. The present process is initiated in response to a command from a higher-level ECU, such as the battery control ECU 60, and is repeatedly performed at a predetermined interval by the arithmetic processing unit 54 of the battery monitoring unit 50. It should be noted that here, as an example, the process of measuring impedance etc. will be described using the battery cell 42B shown in FIG. 4 as the cell to be measured.

In FIG. 5, in step S11, a battery cell 42 to be measured is selected from the plurality of battery cells 42. Here, the battery cell 42B in FIG. 4 is selected, for example. Note that the cell to be measured may include not only the battery cell 42 whose impedances is measured, but also the battery cell 42 whose inter-terminal voltage (for example, open circuit voltage) is measured as the state of the battery cell 42.

Thereafter, in step S12, it is determined whether to perform impedance measurement on the cell to be measured. If the result of step S12 is negative, the process proceeds to step S13. In step S13, the switches 85B and 85C are turned on. As a result, the voltage measurement circuit 86 measures the inter-terminal voltage of the battery cell 42B. In the following step S14, the inter-terminal voltage of the battery cell 42B measured by the voltage measurement circuit 86 is acquired. Then, in step S20, the inter-terminal voltage of the battery cell 42B is transmitted to the higher-level ECU.

In addition, if the result of step S12 is affirmative, the process proceeds to step S15. In step S15, the switches 85A and 85D are turned on. As a result, the voltage measurement circuit 86 measures the inter-terminal voltage of the battery cell group of the battery cells 42A to 42C. In addition, in step S16, the switch 84B is turned on and off to allow the AC current to flow through the battery cell 42B. While the AC current is flowing, the current sensor 83 measures the amplitude of the AC current (current amplitude). According to steps S15 and S16, after the voltage measurement circuit 86 is connected to the electrical path between both ends of the battery cell group by turning on the switch 85, the switch 84 is turned on and off to generate the AC current.

Thereafter, in step S17, the inter-terminal voltage of the battery cell group measured by the voltage measurement circuit 86 is acquired, and in the following step S18, the current amplitude measured by the current sensor 83 is acquired. In step S19, the impedance value is calculated by dividing the voltage fluctuation, which is the response signal of the AC current, by the current amplitude. Note that the voltage fluctuation may be calculated as the voltage difference between the inter-terminal voltage measured before the AC current is passed through the battery cell 42B and the inter-terminal voltage measured while the AC current is passing through the battery cell 42B. It is also possible to use the inter-terminal voltage acquired in step S14 as the inter-terminal voltage before the AC current is passed through the battery cell 42B.

Thereafter, in step S20, the impedance value is transmitted to the higher-level ECU.

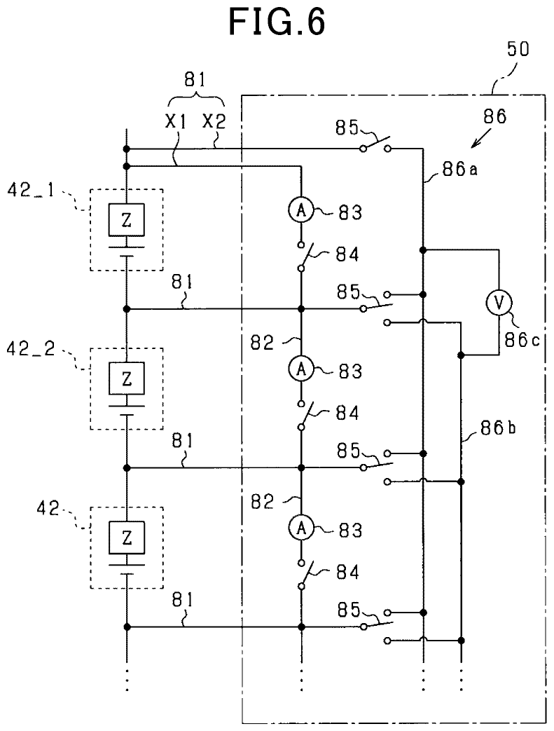

The battery monitoring unit 50 performs impedance measurements for all battery cells 42 in the battery module 41, but cannot perform voltage measurements in the manner shown in FIG. 4 for the battery cell 42 with a highest potential and the battery cell 42 with a lowest potential among the plurality of battery cells 42 included in the battery module 41 (i.e., the battery cell 42 at the end of the series connection of the battery module 41). A method for measuring the impedance of the battery cell 42 at the end of the series connection will be described below with reference to FIGS. 6 to 8.

In FIG. 6, in the battery module 41, among the plurality of battery cells 42 connected in series, the first battery cell 42 on the highest potential side is defined as a battery cell 42_1, and the second battery cell 42 is defined as a battery cell 42_2. The battery cell 42_1 is the battery cell on the highest potential side in the battery module 41, that is, the highest potential cell. In FIG. 6, an electrical path 81 is connected to the positive electrode side of the battery cell 42_1, and includes two branched electrical paths X1 and X2. A current sensor 83 and a switch 84 are connected in series to the electrical path X1, and a positive electrode side path 86a of a voltage measurement circuit 86 is connected to the electrical path X2 via a switch 85. Note that the electrical path X1 corresponds to a first positive electrode side path, and the electrical path X2 corresponds to a second positive electrode side path.

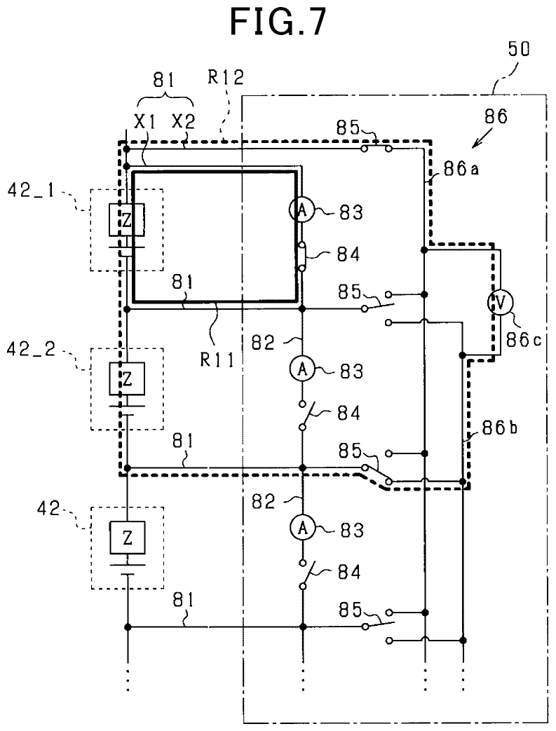

FIG. 7 is a diagram showing a state in which impedance measurement is performed on the battery cell 42_1 as the cell to be measured. In FIG. 7, a path R11 through which an AC current flows is indicated by a thick solid line, and a path R12 for measuring a voltage is indicated by a thick dashed line.

When the battery cell 42_1 on the highest potential side is the cell to be measured, an AC current flows through the battery cell 42_1 by turning on and off the switch 84 on the path connecting both ends of the battery cell 42_1 at a predetermined cycle. At this time, the AC current flows through the path R11 that includes the battery cell 42_1 and the electrical paths X1 and X81 at both ends of the battery cell 42_1.

In addition, the voltage measurement circuit 86 measures the inter-terminal voltage of the battery cell group including the battery cell 42_1 and the adjacent battery cell 42_2 as the measurement target. Specifically, by switching between the switch 85 on the positive side of battery cell 42_1 and the switch 85 on the negative side of battery cell 42_2, voltage fluctuations are measured on the path R12 that includes the battery cell group of the battery cells 42_1 and 42_2, the electrical paths X2 and 81 at both ends of the battery cell group, and the voltage measurement circuit 86. Then, the impedance value of the battery cell 42_1 is calculated based on the voltage fluctuation measured by the voltage measurement circuit 86 and the amplitude of the AC current measured by the current sensor 83.

Note that when measuring the impedance of the highest potential cell, the voltage measurement circuit 86 is configured to measure the voltage fluctuation of the battery cell group using the electrical path X2 on the positive electrode side of the battery cell 42_1 (highest potential cell) and the electrical path 81 on the negative electrode side of the battery cell group that includes at least the battery cell 42_1 and the adjacent battery cell 42_2 on the low potential side. In other words, the battery cell group to be measured for voltage fluctuations may include one or more battery cells 42 on the negative electrode side of the battery cell 42_1 (the cell with the highest potential).

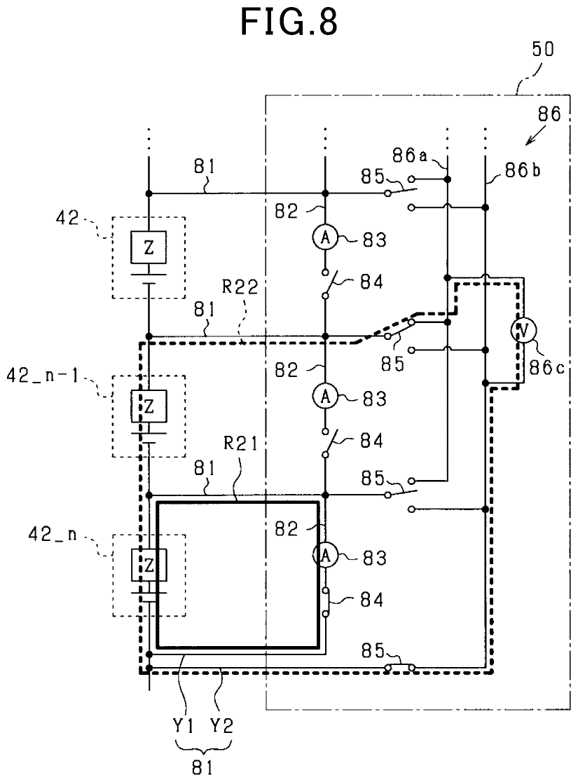

In FIG. 8, in the battery module 41, among a plurality (n) of battery cells 42 connected in series, the nth battery cell 42 on the lowest potential side is a battery cell 42_n, and the n-1th battery cell 42 is a battery cell 42_n-1, and impedance measurement is performed on the battery cell 42 n as the cell to be measured. The battery cell 42_n is the battery cell on the lowest potential side in the battery module 41, that is, the lowest potential cell. In FIG. 8, an electrical path 81 is connected to the negative electrode side of the battery cell 42_n, and includes two branched electrical paths Y1 and Y2. A current sensor 83 and a switch 84 are connected in series to the electrical path Y1, and a negative electrode side path 86b of a voltage measurement circuit 86 is connected to the electrical path Y2 via a switch 85. Note that the electrical path Y1 corresponds to a first negative electrode side path, and the electrical path Y2 corresponds to a second negative electrode side path. In FIG. 8, a path R21 through which an AC current flows is indicated by a thick solid line, and a path R22 for measuring a voltage is indicated by a thick dashed line.

When the battery cell 42_n on the lowest potential side is the cell to be measured, an AC current flows through the battery cell 42_n by turning on and off the switch 84 on the path connecting both ends of the battery cell 42_n at a predetermined cycle. At this time, the AC current flows through the path R21 that includes the battery cell 42_n and the electrical paths Y1 and Y81 at both ends of the battery cell 42_n.

In addition, the voltage measurement circuit 86 measures the inter-terminal voltage of the battery cell group including the battery cell 42_n and the adjacent battery cell 42_n-1 as the measurement target. Specifically, by switching between the switch 85 on the negative side of battery cell 42_n and the switch 85 on the positive side of battery cell 42_n-1, voltage fluctuations are measured in the path R22 that includes the battery cell group of the battery cells 42_n, 42_n-1, the electrical paths Y2, 81 at both ends of the battery cell group, and the voltage measurement circuit 86. Then, the impedance value of the battery cell 42_n is calculated based on the voltage fluctuation measured by the voltage measurement circuit 86 and the amplitude of the AC current measured by the current sensor 83.

Note that when measuring the impedance of the lowest potential cell, the voltage measurement circuit 86 is configured to measure the voltage fluctuation of the battery cell group using the electrical path Y2 on the negative electrode side of the battery cell 42_n (lowest potential cell) and the electrical path 81 on the positive electrode side of the battery cell group that includes at least the battery cell 42_n and the adjacent battery cell 42_n-1 on the low potential side. In other words, the battery cell group to be measured for voltage fluctuations may include one or more battery cells 42 on the positive electrode side of the battery cell 42_n (the lowest potential cell).

Unlike FIGS. 6 to 8, the electrical path 81 on the positive side of the highest potential cell (battery cell 42_1) and the electrical path 81 on the negative side of the lowest potential cell (battery cell 42_n) may not be branched into two paths. In this case, when measuring the impedance of the highest potential cell and the lowest potential cell as the cell to be measured, the electrical path through which the AC current flows and the electrical path through which the voltage fluctuation is measured are common on either the positive or negative side of the cell to be measured, but if the electrical path through which the AC current flows and the electrical path through which the voltage fluctuation is measured are different on the other side, the measurement error will be relatively small.

According to the present embodiment described above in detail, the following excellent effects can be obtained.

When measuring the impedance of one of the plurality of battery cells 42 as the cell to be measured, the AC current from the AC current generating unit 51 is caused to flow through the electrical path 81 at both ends of the cell to be measured, and the voltage measurement circuit 86 is connected to the electrical path 81 at both ends of the battery cell group including at least the cell to be measured and the battery cells 42 adjacent to it on both sides. In this case, the electrical path 81 through which the AC current flows is different from the electrical path 81 through which the voltage fluctuation is measured. Then, in this path connection state, the impedance value of the cell to be measured is calculated based on the amplitude of the AC current flowing from the

AC current generating unit 51 and the voltage fluctuation measured by the voltage measurement circuit 86. This makes it possible to suppress the inconvenience of a voltage drop from occurring due to the wiring resistance and the AC current when the AC current flows, such as a decrease in the accuracy of measuring voltage fluctuations due to the voltage drop. As a result, the accuracy of measuring the impedance can be improved.

When measuring the impedance of the cell to be measured, first, the switch 85 (second switch) is turned on to connect the voltage measurement circuit 86 to the electrical path between both ends of the battery cell group including the cell to be measured, and then, the AC current is caused to flow by turning on and off the switch 84 (first switch) on the path connecting both ends of the cell to be measured. In this case, power consumption can be reduced compared to the case where, conversely, the AC current is started to flow by turning the switch 84 on and off, and then the switch 85 is turned on to enable voltage measurement by the voltage measurement circuit 86.

When measuring the impedance of the highest potential cell (battery cell 42_1), the AC current from the AC current generating unit 51 is passed between both ends of the highest potential cell using the electrical path X1, among the electrical paths X1 and X2 connected to the positive electrode side of the highest potential cell, and the electrical path 81 on the negative electrode side of the highest potential cell. In addition, the voltage measurement circuit 86 measures voltage between both ends of the battery cell group using the electrical path X2 among the electrical paths X1, X2 on the positive electrode side of the highest potential cell and the electrical path 81 on the negative electrode side of the battery cell group that includes at least the highest potential cell and the adjacent battery cell 42 on the low potential side. As a result, when measuring the impedance of the highest potential cell, the electrical path through which the AC current flows and the electrical path through which voltage fluctuations are measured are different, thereby improving the accuracy of impedance measurement.

When measuring the impedance of the lowest potential cell (battery cell 42_n), the AC current from the AC current generating unit 51 is passed to both ends of the lowest potential cell using the electrical path Y1 of the electrical paths Y1 and Y2 connected to the negative electrode side of the lowest potential cell and the electrical path 81 on the positive electrode side of the lowest potential cell. In addition, the voltage measurement circuit 86 measures voltage between both ends of the battery cell group using the electrical path Y2 of the electrical paths Y1, Y2 on the negative electrode side of the lowest potential cell and the electrical path 81 on the positive electrode side of the battery cell group that includes at least the lowest potential cell and the adjacent battery cell 42 on the high potential side. As a result, when measuring the impedance of the lowest potential cell, the electrical path through which the AC current flows and the electrical path through which the voltage fluctuation is measured are different, thereby improving the accuracy of the impedance measurement.

Note that in each battery module 41, the electrical paths 81 connected to both ends of each battery cell 42 that branch into two paths are limited to only the electrical path 81 on the positive electrode side of the highest potential cell and the electrical path 81 on the negative electrode side of the lowest potential cell. Therefore, the increase in cost due to the increase in the number of electrical paths 81 can be minimized.

### Second Embodiment

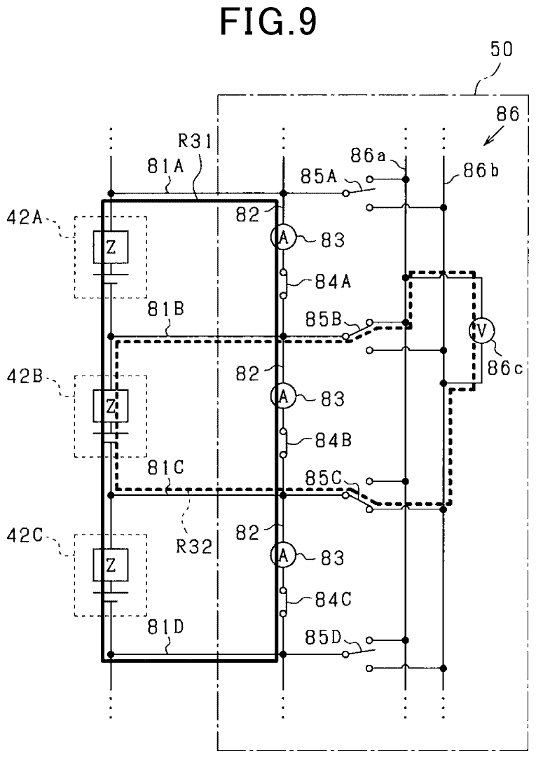

In the present embodiment, the impedance measurement method described with reference to FIG. 4 is modified, and the impedance measurement method in the present embodiment will be described with reference to FIG. 9.

In FIG. 9, similarly to FIG. 4, three battery cells 42 connected in series are defined as battery cells 42A to 42C, and among these, the battery cell 42B is defined as the cell to be measured for impedance measurement. In FIG. 9, a path R31 through which an AC current flows is indicated by a thick solid line, and a path R32 for measuring a voltage is indicated by a thick dashed line.

When the battery cell 42B is the cell to be measured, all of switches 84A to 84C are turned on and off simultaneously at a predetermined cycle, causing the AC current to flow through a battery cell group including the battery cell 42B and the battery cells 42A and 42C on either side of the battery cell 42B. At this time, the AC current flows through the path R31 that includes the battery cell group of the battery cells 42A to 42C, electrical paths 81A and 81D at both ends of the battery cell group, and connection paths 82A to 82C.

In addition, the voltage measurement circuit 86 measures the inter-terminal voltage of the battery cell 42B as the measurement target. Specifically, by switching a switch 85B, the positive electrode side electrical path 81B of the battery cell 42B is connected to a positive electrode side path 86a of the voltage measurement circuit 86, and by switching a switch 85C, the negative electrode side electrical path 81B of the battery cell 42B is connected to a negative electrode side path 86b of the voltage measurement circuit 86. As a result, voltage fluctuations are measured on a path R32 that includes the battery cell 42B, the electrical paths 81B and 81C at both ends of the battery cell 42B, and the voltage measurement circuit 86. Then, the impedance value of the battery cell 42B is calculated based on the voltage fluctuation measured by the voltage measurement circuit 86 and the amplitude of the AC current measured by a current sensor 83.

Note that although the configuration is such that AC current flows through three battery cells 42 including the cell to be measured (battery cell 42B) and the battery cells 42A and 42C adjacent to it by turning on and off the switches 84A to 84C, this configuration may be any configuration that flows the AC current through the electrical path 81 at both ends of the battery cell group that includes at least the cell to be measured and the battery cells 42 adjacent to it. That is, the battery cell group through which the AC current flows may be any group that includes one or more battery cells 42 on both the positive and negative sides of the cell to be measured.

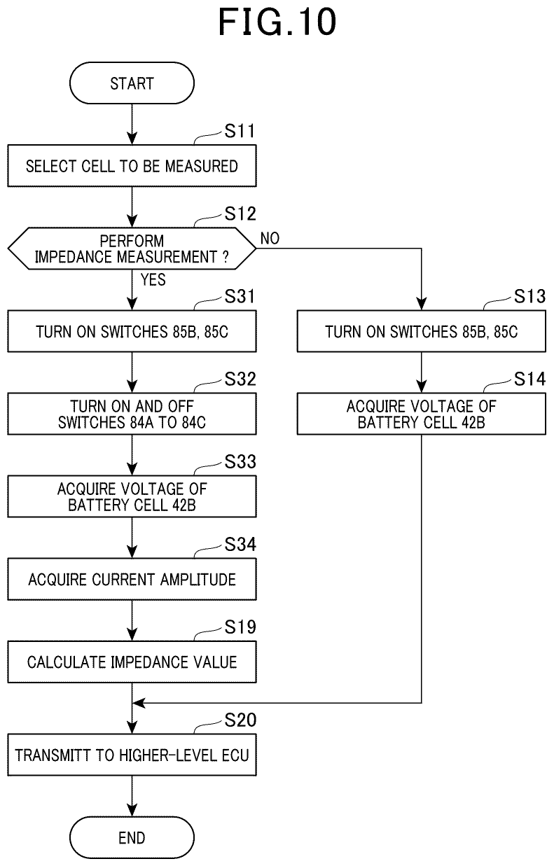

FIG. 10 is a flowchart showing the battery monitoring process in the present embodiment. This process is initiated in response to a command from a higher-level ECU, such as the battery control ECU 60, and is repeatedly performed at a predetermined interval by the arithmetic processing unit 54 of the battery monitoring unit 50. Note that as an example, the process of measuring impedance and the like will be described using the battery cell 42B shown in FIG. 9 as the cell to be measured.

The process in FIG. 10 is a partial modification of the process in FIG. 5, and the same steps as those in FIG. 5 are denoted by the same step numbers. Here, differences from FIG. 5 will be explained.

In FIG. 10, if the result of step S12 is affirmative, the process proceeds to step S31. In step S31, the switches 85B and 85C are turned on. This causes the voltage measurement circuit 86 to measure the inter-terminal voltage of the battery cell 42B. In addition, in step S32, the switches 84A to 84C are simultaneously turned on and off to allow the AC current to flow through the battery cell group of the battery cells 42A to 42C. While the AC current is flowing, the current sensor 83 measures the amplitude of the AC current (current amplitude). According to steps S31 and S32, the switch 84 is turned on and off to generate an AC current after the voltage measurement circuit 86 is connected to the electrical path across the battery cell 42B by turning on the switch 85.

Thereafter, in step S33, the inter-terminal voltage of the battery cell 42B measured by the voltage measurement circuit 86 is acquired, and in the following step S34, the current amplitude measured by the current sensor 83 is acquired. In step S19, the impedance value is calculated by dividing the voltage fluctuation, which is the response signal of the AC current, by the current amplitude. Thereafter, in step S20, the impedance value is transmitted to the higher-level ECU.

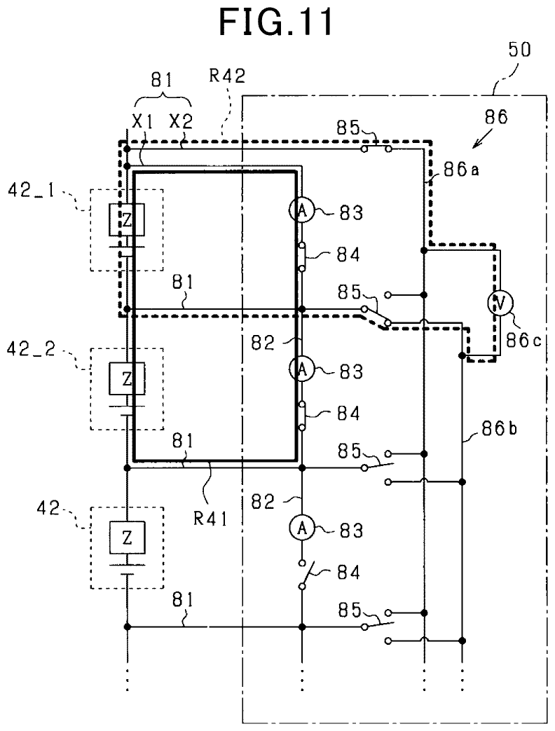

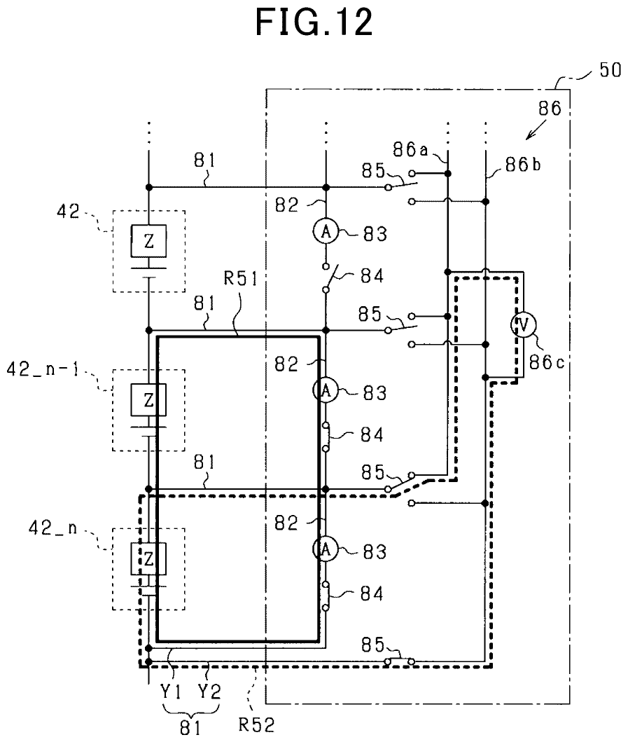

Next, a method for measuring the impedance of the highest potential cell and the lowest potential cell of the battery module 41 (i.e., the battery cell 42 at the end of the series connection) will be described with reference to FIGS. 11 and 12. Note that the circuit configurations in FIGS. 11 and 12 are the same as those in FIGS. 6 to 8.

FIG. 11 is a diagram showing a state in which impedance measurement is performed with the highest potential cell (battery cell 42_1) as the cell to be measured. In FIG. 11, a path R41 through which an AC current flows is indicated by a thick solid line, and a path R42 for measuring a voltage is indicated by a thick dashed line.

When the battery cell 42_1 on the highest potential side is the cell to be measured, two switches 84 on the path connecting both ends of the battery cell group including the battery cell 42_1 and the adjacent battery cell 42_2 are simultaneously turned on and off at a predetermined cycle. As a result, the AC current flows through the path R41 including the battery cell group of the battery cells 42_1 and 42_2 and electrical paths X1 and X81 at both ends of the battery cell group.

In addition, the voltage measurement circuit 86 measures the inter-terminal voltage of the battery cell 42_1 as the measurement target. Specifically, by switching between the switch 85 on the positive side of the battery cell 42_1 and the switch 85 on the negative side of the battery cell 42_1, voltage fluctuations are measured on the path R42 that includes the battery cell 42_1, the electrical paths X2, 81 at both ends of the battery cell 42_1, and the voltage measurement circuit 86. Then, the impedance value of the battery cell 42_1 is calculated based on the voltage fluctuation measured by the voltage measurement circuit 86 and the amplitude of the AC current measured by a current sensor 83.

Note that when measuring the impedance of the highest potential cell (battery cell 42_1), the battery cell group through which the AC current flows may include one or more battery cells 42 on the negative electrode side of the highest potential cell.

FIG. 12 is a diagram showing a state in which impedance measurement is performed with the lowest potential cell (battery cell 42_n) as the cell to be measured. In FIG. 12, a path R51 through which an AC current flows is indicated by a thick solid line, and a path R52 for measuring a voltage is indicated by a thick dashed line.

When the battery cell 42_n on the lowest potential side is the cell to be measured, two switches 84 on the path connecting both ends of the battery cell group including the battery cell 42_n and the adjacent battery cell 42_n-1 are simultaneously turned on and off at a predetermined cycle. As a result, the AC current flows through a path R51 including the battery cell group of the battery cells 42_n and 42_n-1 and electrical paths Y1 and Y81 at both ends of the battery cell group.

In addition, the voltage measurement circuit 86 measures the inter-terminal voltage of the battery cell 42_n as the measurement target. Specifically, by switching between the switch 85 on the negative side of the battery cell 42_n and the switch 85 on the positive side of the battery cell 42_n, voltage fluctuations are measured in a path R52 that includes the battery cell 42_n, the electrical paths Y2, 81 at both ends of the battery cell 42_n, and the voltage measurement circuit 86. Then, the impedance value of the battery cell 42_n is calculated based on the voltage fluctuation measured by the voltage measurement circuit 86 and the amplitude of the AC current measured by the current sensor 83.

Note that when measuring the impedance of the lowest potential cell (battery cell 42_n), the battery cell group through which the AC current flows may include one or more battery cells 42 on the positive electrode side of the lowest potential cell.

Unlike FIGS. 11 and 12, the electrical path 81 on the positive electrode side of the highest potential cell (battery cell 42_1) and the electrical path 81 on the negative electrode side of the lowest potential cell (battery cell 42_n) may not be configured to branch into two paths. In this case, when measuring the impedance of the highest potential cell and the lowest potential cell as the cell to be measured, the electrical path through which the AC current flows and the electrical path through which the voltage fluctuation is measured are common on either the positive or negative side of the cell to be measured, but if the electrical path through which the AC current flows and the electrical path through which the voltage fluctuation is measured are different on the other side, the measurement error will be relatively small.

According to the present embodiment, the following effects can be obtained.

When measuring the impedance of one of the plurality of battery cells 42 as the cell to be measured, the AC current from the AC current generating unit 51 is caused to flow through the electrical path 81 at both ends of the battery cell group including at least the cell to be measured and the battery cells 42 on both sides of the cell to be measured, and the voltage measurement circuit 86 is connected to the electrical path 81 at both ends of the cell to be measured. In this case, the electrical path 81 through which the AC current flows is different from the electrical path 81 through which the voltage fluctuation is measured. Then, in this path connection state, the impedance value of the cell to be measured is calculated based on the amplitude of the AC current flowing from the AC current generating unit 51 and the voltage fluctuation measured by the voltage measurement circuit 86. This makes it possible to suppress the inconvenience of a voltage drop from occurring due to the wiring resistance and the AC current when the AC current flows, such as a decrease in the accuracy of measuring voltage fluctuations due to the voltage drop. As a result, the accuracy of measuring the impedance can be improved.

When measuring the impedance of the cell to be measured, first, the switch 85 (second switch) is turned on to connect the voltage measurement circuit 86 to the electrical path between both ends of the cell to be measured, and then the switch 84 (first switch) on the path connecting both ends of the battery cell group including the cell to be measured is turned on and off to allow the AC current to flow. In this case, power consumption can be reduced compared to the case where, conversely, the AC current begins to flow by turning the switch 84 on and off, and then the switch 85 is turned on to enable voltage measurement by the voltage measurement circuit 86.

When measuring the impedance of the highest potential cell (battery cell 42_1), the AC current from the AC current generating unit 51 is caused to flow across both ends of the battery cell group using the electrical path X1 among the electrical paths X1 and X2 connected to the positive electrode side of the highest potential cell and the electrical path 81 on the negative electrode side of the battery cell group including at least the highest potential cell and the adjacent battery cell 42 on the low potential side. In addition, the voltage measurement circuit 86 measures the voltage across the highest potential cell using the electrical path X2 among the electrical paths X1 and X2 on the positive electrode side and the electrical path 81 on the negative electrode side. As a result, when measuring the impedance of the highest potential cell, the electrical path through which the AC current flows and the electrical path through which the voltage fluctuations are measured are different, thereby improving the accuracy of impedance measurement.

When measuring the impedance of the lowest potential cell (battery cell 42_n), the AC current from the AC current generating unit 51 is passed to both ends of the battery cell group using the electrical path Y1 among the electrical paths Y1 and Y2 connected to the negative electrode side of the lowest potential cell and the electrical path 81 on the positive electrode side of the battery cell group including at least the lowest potential cell and the adjacent battery cell 42 on the high potential side. In addition, the voltage measurement circuit 86 measures the voltage across the lowest potential cell using the electrical path Y2 among the electrical paths Y1 and Y2 on the negative electrode side and the electrical path 81 on the positive electrode side. As a result, when measuring the impedance of the lowest potential cell, the electrical path through which the AC current flows and the electrical path through which the voltage fluctuation is measured are different, thereby improving the accuracy of the impedance measurement.

### Third Embodiment

In the present embodiment, a specific configuration example regarding the connection between each battery cell 42 of the battery module 41 and the AC current generating unit 51 (switch 84) and the voltage measurement circuit 86 will be described.

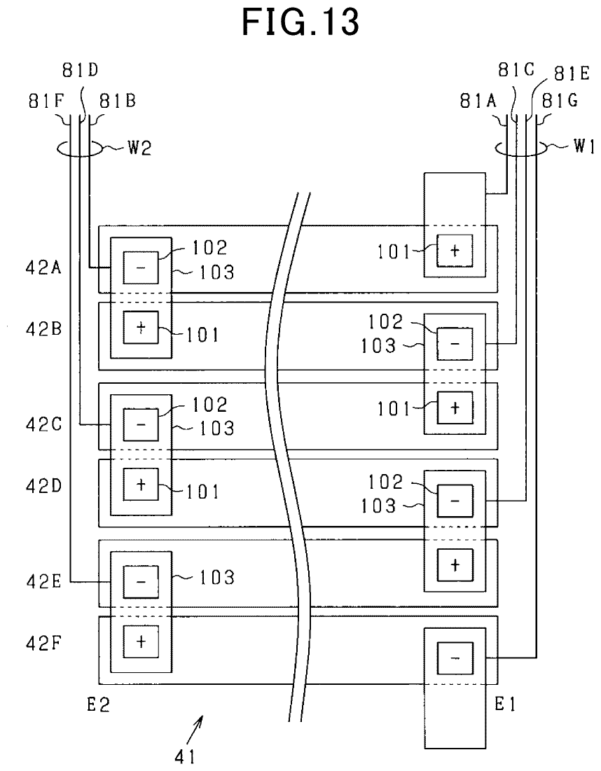

FIG. 13 is a plan view showing a state in which a plurality of battery cells 42 are stacked in a battery module 41. Here, the plurality of battery cells 42 are shown as six battery cells 42, battery cell 42A to battery cell 42F. Each battery cell 42 is a so-called blade cell having a long plate shape (a flat rectangular parallelepiped shape), and is stacked and arranged with plate surfaces facing each other in a plate thickness direction. Each battery cell 42 has a positive terminal 101 at one end in the longitudinal direction of the cell (left-right direction in the drawing) and a negative terminal 102 at the other end, and is disposed in a direction perpendicular to the longitudinal direction of the cell. In the battery module 41, the battery cells 42 are disposed in series connection order such that the positive terminals 101 and the negative terminals 102 alternate in the longitudinal direction of the cells. That is, the battery cells 42 are stacked so that the positive and negative electrode sides are oriented alternately.

In the battery module 41, the positive terminal 101 of one of the adjacent battery cells 42 in the stacking direction (i.e., the consecutive battery cells 42 in the order of series connection) is electrically connected to the negative terminal 102 of the other battery cell 42 by a bus bar 103, which is a conductive member. As a result, the battery cells 42 are connected in series.

In the present embodiment, in the battery module 41, an end on one end side of the cell longitudinal direction (the right end side in the drawing) is defined as a first battery end E1, and the end on the other end side (the left end side in the drawing) is defined as a second battery end E2. In this case, at the first battery end E1, the positive and negative terminals of the battery cells 42B and 42C and the positive and negative terminals of the battery cells 42D and 42E are electrically connected by the bus bars 103, respectively. In addition, at the second battery end E2, the positive and negative terminals of the battery cells 42A and 42B, the positive and negative terminals of the battery cells 42C and 42D, and the positive and negative terminals of the battery cells 42E and 42F are electrically connected by bus bars 103, respectively.

At the first battery end E1 and the second battery end E2, the bus bars 103 are connected to electrical paths 81, respectively. As a result, the electrical paths 81 are connected to both ends of respective battery cells 42 connected in series. Here, the electrical paths 81 are defined as electrical paths 81A, 81B, 81C, 81D, 81E, 81F, and 81G in accordance with the order of the series connection of the battery cells 42A to 42F. In addition, the electrical paths 81A, 81C, 81E, and 81G on the first battery end E1 side are defined as first electrical paths W1, and the electrical paths 81B, 81D, and 81F on the second battery end E2 side are defined as second electrical paths W2.

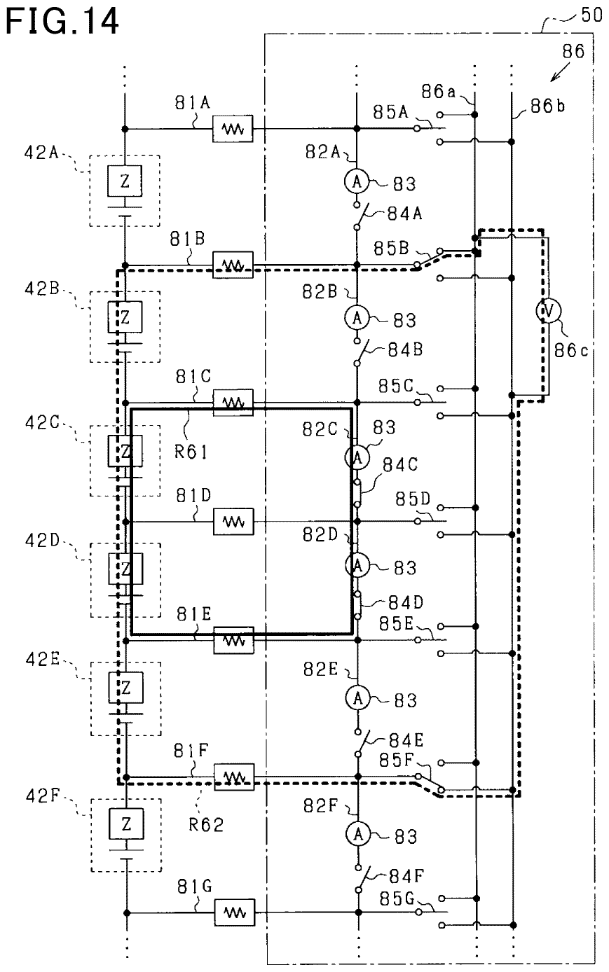

FIG. 14 is a circuit diagram showing a specific circuit configuration of a battery monitoring unit 50 for a battery module 41 having six battery cells 42A to 42F connected in series. The battery monitoring unit 50 in FIG. 14 has a similar configuration to those in FIGS. 3 and 4 described above, although the number of cells is different, and electrical paths 81A to 81G are provided for each of the battery cells 42A to 42F, and current sensors 83 and switches 84A to 84F are provided on connection paths 82A to 82F corresponding to each of the battery cells 42A to 42F, respectively. In addition, a voltage measurement circuit 86 is connected to the electrical paths 81A to 81G via switches 85A to 85G.

FIG. 14 shows a state in which impedance measurement is performed on the battery cells 42C and 42D among the battery cells 42A to 42F as the cells to be measured. In FIG. 14, a path R61, through which an AC current flows, is indicated by a thick solid line, and a path R62 for measuring a voltage is indicated by a thick dashed line.

When measuring the impedance of the battery cells 42C and 42D, the switches 84C and 84D on the path connecting both ends of the battery cells 42C and 42D are simultaneously turned on and off at a predetermined cycle. As a result, the AC current flows through a path R61 that includes the battery cells 42C and 42D, the electrical paths 81C and 81E at both ends of the battery cells 42C and 42D, and the connection paths 82C and 82D.

In addition, the voltage measurement circuit 86 measures the inter-terminal voltage of a battery cell group including the battery cells 42C and 42D and the battery cells 42B and 42E adjacent to the battery cells 42C and 42D. Specifically, by switching the switch 85B, the positive electrode side electrical path 81B of battery cell 42B is connected to a positive electrode side path 86a of the voltage measurement circuit 86, and by switching the switch 85F, the negative electrode side electrical path 81F of battery cell 42E is connected to a negative electrode side path 86b of the voltage measurement circuit 86. As a result, the voltage fluctuations are measured on the path R62 that includes the battery cell group of the battery cells 42B to 42E, the electrical paths 81B and 81F at both ends of the battery cell group, and the voltage measurement circuit 86. Then, the impedance values of the battery cells 42C and 42D are calculated based on the voltage fluctuation measured by the voltage measurement circuit 86 and the amplitude of the AC current measured by the current sensor 83.

Here, comparing the electrical paths 81A to 81G connected to each battery cell 42A to 42F with the battery structure of FIG. 13, the AC current flowing through the battery cells 42C and 42D flows via the electrical paths 81C and 81E, which are the first electrical path W1 on the first battery end E1 side. In this case, the electrical path 81C extending from the positive electrode side of the battery cell 42C and the electrical path 81E extending from the negative electrode side of the battery cell 42D are electrical paths drawn out from the same end side (first battery end E1 side) of both ends of the cell longitudinal direction in the battery module 41. Therefore, when a closed circuit (path R61) is formed by battery cells 42C and 42D, each electrical path 81C and 81E, and connection paths 82C and 82D, an area enclosed by the closed circuit becomes smaller, and the magnetic flux generated by the alternating current is reduced.

In addition, the inter-terminal voltage of the battery cell group composed of the battery cells 42B to 42E is measured via the electrical paths 81B and 81F, which are the second electrical path W2 on the second battery end E2 side. In this case, the electrical path 81B extending from the positive electrode side of the battery cell 42B and the electrical path 81F extending from the negative electrode side of the battery cell 42E are electrical paths drawn out from the same end side (the second battery end E2 side) of both ends of the cell longitudinal direction in the battery module 41. Therefore, when a closed circuit (path R62) is formed by the battery cells 42B and 42E, each electrical path 81B and 81F, and the voltage measurement circuit 86, an area enclosed by the closed circuit becomes smaller, and the influence of the induced electromotive force is reduced.

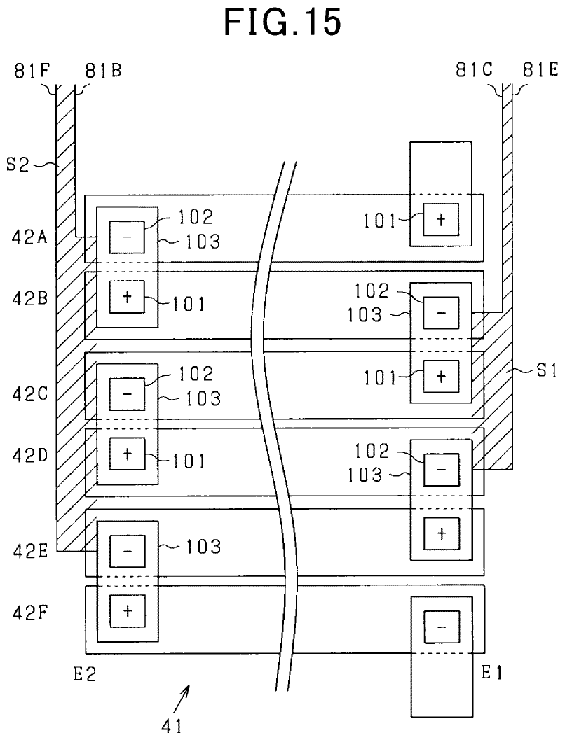

FIG. 15 is a schematic diagram showing the closed-circuit area when measuring the impedance of the battery cells 42C and 42D in the battery module 41. Note that in FIG. 15, the closed-circuit area formed by the AC current flow path is defined as an area S1, and the closed-circuit area formed by the path for measuring the voltage response is defined as an area S2, and these areas S1 and S2 are indicated by hatching.

The electrical paths 81C and 81E that form the current paths for the AC current both extend from the first battery end E1 side of the battery module 41, and the area surrounded by the electrical paths 81C and 81E is the area S1. In this case, if the impedance is measured only for the battery cell 42C and the AC current is passed through the electrical paths 81C and 81D at both ends of the battery cell 42C, the closed-circuit area formed by the electrical paths 81C and 81E (AC current flow paths) will be wider because the electrical paths 81C and 81D are located at both ends of the cell in the longitudinal direction. Therefore, there is a concern that the magnetic flux generated by the AC current will become large. In contrast, when an AC current path is formed as shown in FIG. 14, the electrical paths 81C and 81E extending from both ends of the battery cells 42C and 42D are relatively close to each other, so that the magnetic flux generated by the AC current can be reduced.

In addition, the electrical paths 81B and 81F connected to the voltage measurement circuit 86 both extend from the second battery end E2 side of the battery module 41, and the area surrounded by these electrical paths 81B and 81F is the area S2. In this case, in the closed circuit for measuring the voltage response, the area through which the magnetic flux generated by the AC current passes can be made smaller than in a configuration in which two electrical paths spaced apart in the longitudinal direction of the cells of the battery module 41 are connected to the voltage measurement circuit 86. This improves the accuracy of measurement of weak voltage response signals.

The battery monitoring process of the present embodiment, which is performed by the arithmetic processing unit 54 of the battery monitoring unit 50, will now be briefly described with reference to the flowchart of FIG. 5.

In the battery monitoring process of FIG. 5, when impedance measurement is performed on the battery cells 42C and 42D as the cell to be measured, for example, the switches 85B and 85F are turned on (step S15). This allows the voltage measurement circuit 86 to measure the inter-terminal voltage of the battery cell group of the battery cells 42B to 42E. In addition, the switches 84C and 84D are turned on and off to allow the AC current to flow through the battery cells 42C and 42D (step S16). Thereafter, the inter-terminal voltage of the battery cell group measured by the voltage measurement circuit 86 and the current amplitude measured by the current sensor 83 are acquired (steps S17 and S18), and the impedance value is calculated by dividing the voltage fluctuation, which is the response signal of the AC current, by the current amplitude (step S19).

Note that in the battery module 41, it is preferable to measure the impedance of each of the battery cells 42A to 42F in pairs in the order of their series connection. At this time, the impedance may be measured for a pair of battery cells 42 that do not overlap each other, or the impedance may be measured for a pair of battery cells 42 that are shifted by one cell to form different combinations.

According to the present embodiment described above, the following effects can be obtained.

In the battery cell 42, the positive terminal 101 and the negative terminal 102 are disposed on one end side and the other end side in the longitudinal direction of the cell, and when the connection positions of the positive and negative terminals of the cells alternate in the order of series connection, the electrical paths 81 connected to both ends of each battery cell 42 are disposed separately on one end side and the other end side in the longitudinal direction of the cell.

Therefore, the area surrounded by the closed circuit through which the AC current flows and the area surrounded by the closed circuit through which the voltage response is measured become large, which raises concerns about a decrease in the accuracy of the voltage response signal. In this regard, when measuring the impedance of the cell to be measured, the AC current is passed by the AC current generating unit through the first electrical path W1, which is on the positive and negative sides of the cell to be measured in the series connection path of the plurality of battery cells 42 and is on the first battery end E1 side of the battery module 41. In addition, the voltage measurement circuit 86 (voltage fluctuation measuring unit) is connected to the second electrical path W2, which is on the positive and negative sides of the cell to be measured and is also on the second battery end E2 side of the battery module 41. This makes it possible to narrow the area surrounded by the closed circuit through which the AC current flows and the area surrounded by the closed circuit through which the voltage response is measured, thereby suppressing a decrease in the accuracy of the voltage response signal.

In particular, in the case of a blade cell, in which the longitudinal length of the cell is long and the positive terminal 101 and the negative terminal 102 are far apart, the effect of reducing the influence of induced electromotive force can be significantly achieved by configuring the cell so that the AC current flows through a pair of electrical paths 81 (wiring) at one longitudinal end of the cell and the voltage response is measured through a pair of electrical paths 81 (wiring) at the other end.

### Modification of the Third Embodiment

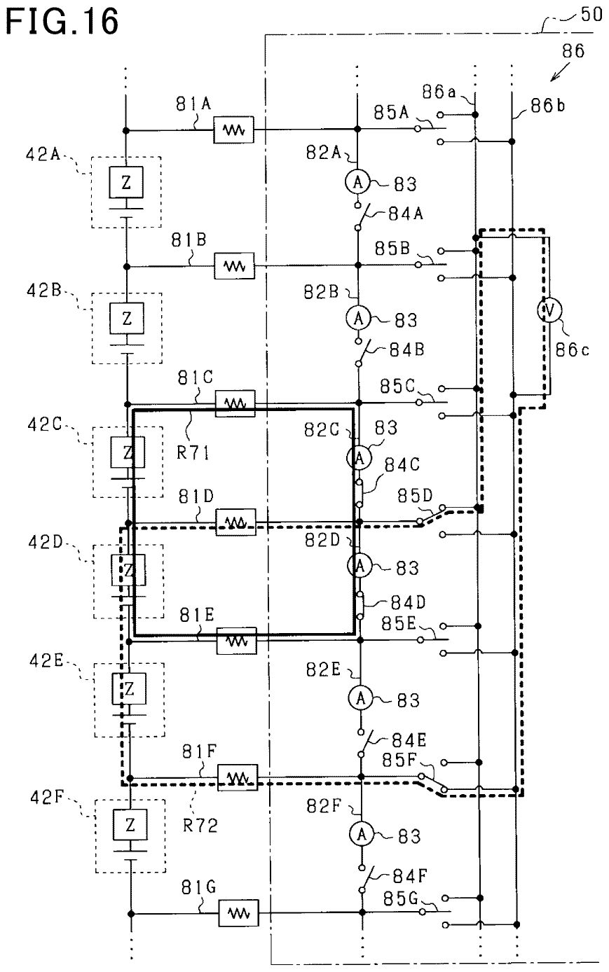

In the circuit configuration shown in FIG. 14, the AC current path during impedance measurement and the path for voltage response measurement may be modified as follows. Here, the impedance of the battery cell 42D is measured as the cell to be measured, and the AC current flow path and the voltage response measurement path are shown in FIG. 16. In FIG. 16, an AC current flow path R71 is shown by a thick solid line, and a voltage measurement path R72 is shown by a thick dashed line.

In FIG. 16, switches 84C and 84D on the path connecting both ends of battery cells 42C and 42D are simultaneously turned on and off at a predetermined cycle. As a result, an AC current flows through the path R71 that includes the battery cells 42C, 42D, electrical paths 81C, 81E at both ends of the battery cells 42C, 42D, and connection paths 82C, 82D.

In addition, a voltage measurement circuit 86 measures the inter-terminal voltage of a battery cell group that includes the battery cell 42D and is a different combination from the battery cells 42C and 42D through which the AC current flows, i.e., the battery cells 42D and 42E. Electrical paths 81D and 81F, which are paths for measuring voltage, may be alternately arranged with the electrical paths 81C and 81E, which carry the AC current. In this case, the positive electrode side electrical path 81D and the negative electrode side electrical path 81F of the battery cell group composed of the battery cells 42D and 42E are connected to the voltage measurement circuit 86 by switching the switches 85D and 85F. As a result, the voltage fluctuations are measured on the path R72 that includes the battery cell group of the battery cells 42D and 42E, the electrical paths 81D and 81F at both ends of the battery cell group, and the voltage measurement circuit 86. Then, for a battery cell 42 (here, battery cell 42D) included in both directions of the path R71 through which the AC current flows and the path R72 for voltage measurement, an impedance value is calculated based on the voltage fluctuation measured by the voltage measurement circuit 86 and the amplitude of the AC current measured by a current sensor 83.

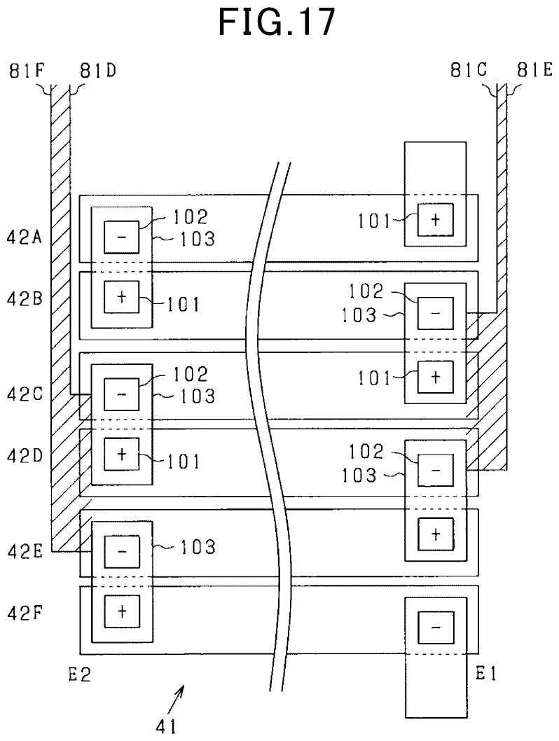

As shown in FIG. 17, the electrical paths 81C and 81E that form the current paths for the AC current are both electrical paths that are drawn out from a first battery end E1 side of the battery module 41. Therefore, when a closed circuit (path R71) is formed by the battery cells 42C, 42D, the electrical paths 81C, 81E, and the connection paths 82C, 82D, an area enclosed by the closed circuit is relatively small. This reduces the magnetic flux generated by the AC current.

In addition, the electrical paths 81D and 81F connected to the voltage measurement circuit 86 are both electrical paths drawn out from a second battery end E2 side of the battery module 41. Therefore, the area through which the magnetic flux generated by the AC current passes can be reduced in the closed circuit where the voltage response is measured. This improves the accuracy of measurements for weak voltage response signals.

In both FIGS. 14 and 16, the AC current is caused to flow through a first electrical path W1, which is on the positive and negative sides of the cell to be measured in the series connection path of the plurality of battery cells 42 and is on the side of the first battery terminal E1 of the battery module 41, by the AC current generating unit, and the voltage fluctuation measuring unit is connected to a second electrical path W2, which is on the positive and negative sides of the cell to be measured and is on the side of the second battery terminal E2 of the battery module 41.

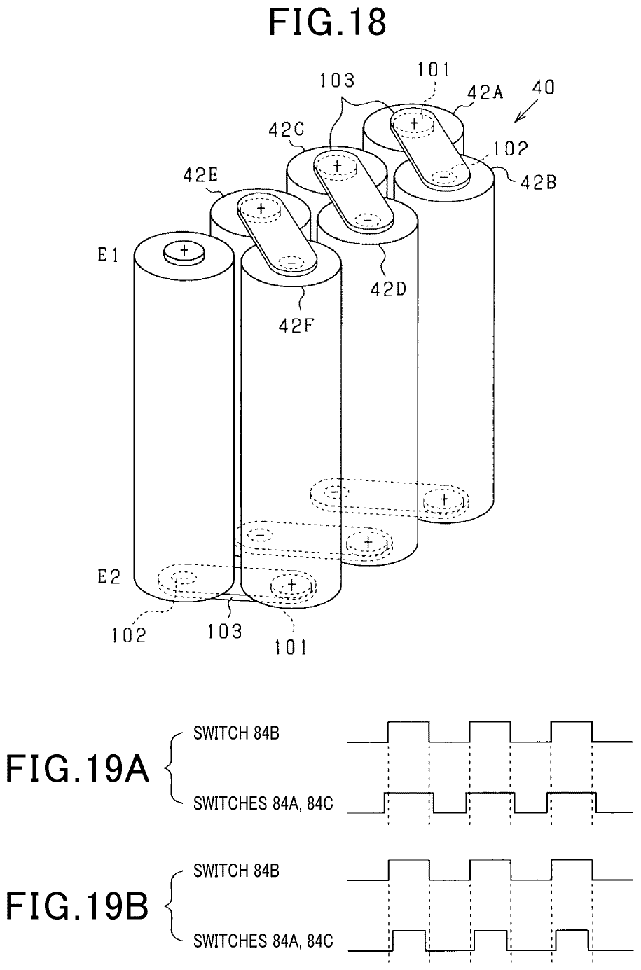

-In the battery module 41, cylindrical cells may be used as the battery cells 42 instead of the long, plate-shaped blade cells. Specifically, as shown in FIG. 18, cylindrical battery cells 42 are arranged in two rows in a staggered pattern. In this configuration, each battery cell 42 is provided with a positive terminal 101 and a negative terminal 102 at one end and the other end in the longitudinal direction of the cell, respectively, and the positive terminals 101 and negative terminals of different battery cells 42 in the series connection order are electrically connected by bus bars 103. In FIG. 18, the upper side is a first battery end E1 of the battery module 41, and the lower side is a second battery end E2 of the battery module 41, and electrical paths 81 are connected to the bus bars 103 of these ends E1, E2, respectively.

### OTHER EMBODIMENTS

The above embodiments may be modified as follows, for example.

-In the second embodiment, when measuring the impedance of the battery cell 42B, which is the cell to be measured, as shown in FIG. 9, the on/off control of the switches 84A to 84C may be controlled as follows. As shown in FIG. 19A, when the switches 84A to 84C are turned on and off, the on time of the switches 84A and 84C on either side may be set longer than the on time of the switch 84B corresponding to the battery cell 42B, which is the cell to be measured (i.e., the middle switch 84B of the three switches 84A to 84C connected in series), so that the switches 84A and 84C on either side are not turned off (opened) while the switch 84B is on (closed). This ensures the accuracy of voltage measurement by the voltage measurement circuit 86 while the switch 84B is on.

Alternatively, as shown in FIG. 19B, when the switches 84A to 84C are turned on and off, the on time of the switches 84A and 84C on either side may be set to be shorter than the on time of the switch 84B corresponding to the battery cell 42B, which is the cell to be measured, so that the adjacent switches 84A and 84C are not turned on (closed) while the switch 84B is off (open). This makes it possible to prevent unnecessary power consumption in the battery cells 42A and 42C caused by the switches 84A and 84C being turned on while the switch 84B is turned off.

-In the second embodiment shown in FIG. 9, when measuring the impedance of the battery cell 42B, all three switches 84A to 84C corresponding to the battery cell group including the battery cell 42B are simultaneously turned on and off to pass an AC current through the battery cell 42B, however, this configuration may be modified. For example, the AC current may be passed through battery cell 42B by turning on or off one of three switches 84A to 84C corresponding to the battery cell group including battery cell 42B, while leaving the remaining two switches 84 in the on state.

In addition, when the AC current is passed through each battery cell 42, an equalizing current may be passed through each battery cell 42 to equalize the voltages of the battery cells 42.

In this case, if there is a battery cell 42 that needs to be discharged for equalization, it is advisable to pass the AC current through a path that includes that battery cell 42. For example, if the battery cell 42B is the cell to be measured and equalized discharge of the battery cell 42A or the battery cell 42C is to be performed when turning on and off the three switches 84A to 84C, it is advisable to make the on time (closed time) of the battery cell 42A or the battery cell 42C longer than the on time of the battery cell 42B.

-When measuring impedance as shown in FIG. 9, it is sufficient that the current sensor 83 is provided in one battery cell 42 of the battery cell group of three battery cells 42. For example, in FIG. 9, it is possible to eliminate any two of the current sensors 83 provided for the three battery cells 42A to 42C.

-In the above embodiments, the battery pack 40 is configured by a plurality of battery modules 41, however, this configuration may be modified. For example, the battery pack 40 may be configured to use one battery module 41, that is, the battery pack 40 and the battery module 41 may be configured to be substantially identical to each other.
The battery pack having a plurality of battery cells may be a fuel cell that generates electrical energy through a chemical reaction between hydrogen and oxygen.
The present disclosure may be applied to other moving bodies, such as aircraft and ships, in addition to electric vehicles. In addition, it may also be applied to a stationary system.

Although the present disclosure has been described with reference to exemplary embodiments, it is understood that the present disclosure is not limited to those exemplary embodiments or structures. The present disclosure also encompasses various modifications and variations within the scope of equivalents. Additionally, various combinations and configurations, as well as other combinations and configurations including only one element, more, or less, are within the scope and ideas of the present disclosure.

1. An impedance measuring device for a battery module having a plurality of battery cells connected in series and measures an impedance of the battery cells, the impedance measuring device comprising:
a plurality of electrical paths respectively connected to both ends of respective battery cells,
an AC current generating unit connected to the electrical paths and supplying an AC current to the battery cells,
a voltage fluctuation measuring unit connected to the electrical paths and configured to measure voltage fluctuations responsive to the AC current of the AC current generating unit,
a connection operation unit that, when measuring impedance of one of the plurality of battery cells as a cell to be measured, causes the AC current of the AC current generating unit to flow through a pair of electrical paths that are on positive and negative sides of the cell to be measured in a series connection path of the plurality of battery cells, and connects the voltage fluctuation measuring unit to the pair of electrical paths that are on the positive and negative sides of the cell to be measured, and that are a different combination from the pair of electrical paths through which the AC current of the AC current generating unit flows, and
a calculation unit that calculates an impedance value of the cell to be measured based on an amplitude of the AC current flowing from the AC current generating unit and a voltage fluctuation measured by the voltage fluctuation measuring unit in a connected state produced by the connection operation unit, wherein
when measuring the impedance of the cell to be measured, the connection operation unit causes the AC current from the AC current generating unit to flow through the electrical paths at both ends of the cell to be measured, and connects the voltage fluctuation measuring unit to the electrical paths at both ends of a battery cell group including at least the cell to be measured and the battery cells on both sides of the cell to be measured, and
the calculation unit causes the AC current from the AC current generating unit to flow through the electrical paths between both ends of the cell to be measured, and the voltage fluctuation measuring unit is connected to the electrical paths between both ends of the battery cell group, and calculates the impedance value of the cell to be measured based on the amplitude of the AC current flowing from the AC current generating unit and the voltage fluctuation measured by the voltage fluctuation measuring unit.

2. The impedance measuring device according to claim 1, wherein
the impedance measuring device further includes:
a first switch provided as the AC current generating unit, which flows the AC current through the battery cell by turning it on and off, and
a second switch connected to respective plurality of electrical paths for switching the battery cell that is a target of voltage measurement by the voltage fluctuation measuring unit, wherein
when measuring the impedance of the cell to be measured, the connection operation unit turns on the second switch to connect the voltage fluctuation measuring unit to the electrical paths between both ends of the battery cell group, and then turns on and off the first switch to allow the AC current to flow.

3. The impedance measuring device according to claim 1, wherein
a first positive electrode side path and a second positive electrode side path are connected as the electrical paths to a positive electrode side of a highest potential cell, which is a battery cell on the highest potential side among the plurality of battery cells, and a first negative electrode side path and a second negative electrode side path are connected as the electrical paths to a negative electrode side of a lowest potential cell, which is a battery cell on the lowest potential side,
when measuring impedance of the highest potential cell as the cell to be measured, the connection operation unit causes the AC current of the AC current generating unit to flow between both ends of the highest potential cell using the first positive electrode side path on the positive electrode side of the highest potential cell and the electrical path on the negative electrode side, and causes the voltage fluctuation measuring unit to measure voltages between both ends of the battery cell group using the second positive electrode side path and the electrical path on the negative electrode side of the battery cell group including at least the highest potential cell and the battery cell adjacent to the highest potential cell on the low potential side, and
when measuring impedance of the lowest potential cell as the cell to be measured, the connection operation unit causes the AC current of the AC current generating unit to flow between both ends of the lowest potential cell using the first negative electrode side path on the negative electrode side of the lowest potential cell and the electrical path on the positive electrode side, and causes the voltage fluctuation measuring unit to measure voltages between both ends of the battery cell group using the second negative electrode side path and the electrical path on the positive electrode side of a battery cell group including at least the lowest potential cell and the battery cell adjacent to the lowest potential cell on the high potential side.

4. The impedance measuring device according to claim 1, wherein
a first positive electrode side path and a second positive electrode side path are connected as the electrical paths to a positive electrode side of a highest potential cell, which is a battery cell on the highest potential side among the plurality of battery cells, and a first negative electrode side path and a second negative electrode side path are connected as the electrical paths to a negative electrode side of a lowest potential cell, which is a battery cell on the lowest potential side,
when measuring impedance of the highest potential cell as the cell to be measured, the connection operation unit causes the AC current of the AC current generating unit to flow between both ends of the highest potential cell using the first positive electrode side path on the positive electrode side of the highest potential cell and the electrical path on the negative electrode side, and causes the voltage fluctuation measuring unit to measure voltages between both ends of the battery cell group using the second positive electrode side path and the electrical path on the negative electrode side of the battery cell group including at least the highest potential cell and the battery cell adjacent to the highest potential cell on the low potential side, and
when measuring impedance of the lowest potential cell as the cell to be measured, the connection operation unit causes the AC current of the AC current generating unit to flow between both ends of the lowest potential cell using the first negative electrode side path on the negative electrode side of the lowest potential cell and the electrical path on the positive electrode side, and causes the voltage fluctuation measuring unit to measure voltages between both ends of the battery cell group using the second negative electrode side path and the electrical path on the positive electrode side of a battery cell group including at least the lowest potential cell and the battery cell adjacent to the lowest potential cell on the high potential side.

5. An impedance measuring device for a battery module having a plurality of battery cells connected in series and measures an impedance of the battery cells, the impedance measuring device comprising:
a plurality of electrical paths respectively connected to both ends of respective battery cells,
an AC current generating unit connected to the electrical paths and supplying an AC current to the battery cells,
a voltage fluctuation measuring unit connected to the electrical paths and configured to measure voltage fluctuations responsive to the AC current of the AC current generating unit,
a connection operation unit that, when measuring impedance of one of the plurality of battery cells as a cell to be measured, causes the AC current of the AC current generating unit to flow through a pair of electrical paths that are on positive and negative sides of the cell to be measured in a series connection path of the plurality of battery cells, and connects the voltage fluctuation measuring unit to the pair of electrical paths that are on the positive and negative sides of the cell to be measured, and that are a different combination from the pair of electrical paths through which the AC current of the AC current generating unit flows, and
a calculation unit that calculates an impedance value of the cell to be measured based on an amplitude of the AC current flowing from the AC current generating unit and a voltage fluctuation measured by the voltage fluctuation measuring unit in a connected state produced by the connection operation unit, wherein
each of the battery cells is elongated, and is arranged in a direction perpendicular to the longitudinal direction of the cell, with a positive terminal provided at one end of the cell in the longitudinal direction and a negative terminal provided at the other end of the cell alternately between adjacent battery cells,
the battery module is configured by electrically connecting the positive terminal of one battery cell and the negative terminal of the other battery cell among battery cells connected in series by a conductive member, and
a first electrical path is connected as the electrical path to the conductive member at a first battery end which is one end side in the cell longitudinal direction of the battery module, and a second electrical path is connected as the electrical path to the conductive member at a second battery end which is the other end side, wherein
when measuring the impedance of the cell to be measured, the connection operation unit causes the AC current generating unit to flow through the first electrical path, which is located on the positive and negative sides of the cell to be measured in the series connection path of the plurality of battery cells and is on the side of the first battery end of the battery module, and also connects the voltage fluctuation measuring unit to the second electrical path, which is located on the positive and negative sides of the cell to be measured and is on the side of the second battery end of the battery module.

6. The impedance measuring device according to claim 2, wherein
a first positive electrode side path and a second positive electrode side path are connected as the electrical paths to a positive electrode side of a highest potential cell, which is a battery cell on the highest potential side among the plurality of battery cells, and a first negative electrode side path and a second negative electrode side path are connected as the electrical paths to a negative electrode side of a lowest potential cell, which is a battery cell on the lowest potential side,
when measuring impedance of the highest potential cell as the cell to be measured, the connection operation unit causes the AC current of the AC current generating unit to flow between both ends of the highest potential cell using the first positive electrode side path on the positive electrode side of the highest potential cell and the electrical path on the negative electrode side, and causes the voltage fluctuation measuring unit to measure voltages between both ends of the battery cell group using the second positive electrode side path and the electrical path on the negative electrode side of the battery cell group including at least the highest potential cell and the battery cell adjacent to the highest potential cell on the low potential side, and
when measuring impedance of the lowest potential cell as the cell to be measured, the connection operation unit causes the AC current of the AC current generating unit to flow between both ends of the lowest potential cell using the first negative electrode side path on the negative electrode side of the lowest potential cell and the electrical path on the positive electrode side, and causes the voltage fluctuation measuring unit to measure voltages between both ends of the battery cell group using the second negative electrode side path and the electrical path on the positive electrode side of a battery cell group including at least the lowest potential cell and the battery cell adjacent to the lowest potential cell on the high potential side.
